(19) United States
(12) Patent Application Publication
(10) Pub. No.: US 2017/0208708 A1
(43) Pub. Date: Jul. 20, 2017

(54) ROBUST REDUNDANT-CAPABLE LEAK-RESISTANT COOLED ENCLOSURE WALL

(71) Applicant: ADC TECHNOLOGIES INC., Montreal (CA)

(72) Inventor: Niall Thomas DAVIDSON, Hamilton (GB)

(21) Appl. No.: 15/324,359

(22) PCT Filed: Jul. 8, 2015
(86) PCT No.: PCT/CA2015/050631

§ 371 Date: Jan. 6, 2017

Related U.S. Application Data
(60) Provisional application No. 62/022,015, filed on Jul. 8, 2014.
(60) Provisional application No. 62/022,032, filed on Jul. 8, 2014.
(60) Provisional application No. 62/022,044, filed on Jul. 8, 2014.
(60) Provisional application No. 62/022,056, filed on Jul. 8, 2014.

(51) Int. Cl. H05K 7/20; F25D 23/06

(52) U.S. Cl. CPC H05K 7/20781; F25D 23/061; H05K 7/20745; H05K 7/20836; H05K 7/20272; H05K 7/20254

(57) ABSTRACT

Disclosed is an enclosure wall assembly of a type which can be used to cool electronic equipment, the electronic equipment characterized by having a rail comprising a thermally conductive surface which is cooled by its installation into a cooled enclosure. The described enclosure wall comprises channels whose cooled surfaces can be cooled by coolant flowing through a coolant guide in thermal contact with each surface. Configurations of coolant guides with fins or pins are described as are coolant guides which enable mission critical cooling via redundant cooling flows. Also disclosed is a method and apparatus for controlling the temperature of coolant supplied to cooled enclosure apparatus in a data center environment. The described coolant delivery system comprising inner and outer pipework separated by a mixing valve, the mixing valve being operable to allow coolant from the outer portion to mix with coolant from the inner portion.

### CROSS-REFERENCES TO RELATED-APPLICATION

The present application claims the benefits of priority of U.S. Provisional Patent Application No. 62/022,044 entitled “Robust Redundant-Capable Leak-Resistant Cooled Enclosure Wall” filed at the United States Patent and Trademark Office on Jul. 8, 2014, the content of which is incorporated herein by reference in its entirety. The present application also claims the benefits of priority of U.S. Provisional Patent Applications Nos. 62/022,015, 62/022,032, 62/022,056 respectively entitled “Computer System with Improved Thermal Rail”, “Efficiently Cooling Data Centers using Thermal Rail Technology” and “Slide Assembly for Thermal Rail Cooled Systems” filed at the USPTO on Jul. 8, 2014 which are incorporated herein by reference in their entirety.

### FIELD OF THE INVENTION

The present disclosure generally relates to cooled enclosure apparatus in a data center environment. More specifically, the present disclosure relates to a wall arrangement for cooled enclosure apparatus and managing the temperature of coolant provided to cooled enclosures to maximize cooling efficiency.

### BACKGROUND

Data centers are a prominent feature of modern life and the cooling of computer systems such as computer servers and network apparatus are a central part of a data centers operation.

The majority of contemporary data centers use air as their primary means of removing heat from computer servers and other equipment. Whilst convenient, air is an inefficient means of transporting heat, and managing air flow and temperatures within a contemporary data center is becoming increasingly complex and challenging.

The cooling technology described in Patent Cooperation Treaty application published as WO 2014/030046 and in the Patent Applications entitled “Computer System with Improved Thermal Rail” comprise a cooled enclosure apparatus, which in cooperation with compatible computer servers and other electronic equipment, can remove heat efficiently and cost effectively without relying on air as the primary means of cooling.

Improvements in any technology is desirable and the present disclosure is directed to cooled enclosure apparatus, and efficiently cooling cooled enclosure apparatus in a data center environment.

### SUMMARY

The present disclosure is directed to a cooled enclosure wall which can be used to cool apparatus of the type described in the Patent Cooperation Treaty application published as WO 2014/030046 and the Patent Application entitled “Computer System with Improved Thermal Rail”. The present disclosure is also directed to efficiently integrating cooled enclosure apparatus into a data center environment and discloses a method of managing the temperature of coolant provided to cooled enclosures to maximize cooling efficiency.

One described cooled enclosure wall comprises a face component comprising a plurality of channels configured to receive a rail of installed equipment. Each channel having a corresponding coolant guide, in the form of an extrusion, arranged on a surface of the face component in such a way that coolant flowing through the coolant guide can effectively cool a surface, the coolable surface, of the channel. In order to improve the effectiveness of the coolant the coolant guide guides the coolant over a plurality of thermally conductive features, in the form of fins, which are in thermal contact with the coolable surface of the channel.

Alternative coolant guides for the described enclosure wall are described including a coolant guide which when used with a suitable coolant distribution system can provide redundant cooling capability to the cooled enclosure wall. Enabling a cooled enclosure wall to be fed by two independent coolant feed and return lines and being capable of adequately cooling installed equipment if coolant flow through either fails.

Structural support is provided to the described enclosure wall by a plurality of supports which, in cooperation with the coolant guides, provide support for each channel. The face component, supports and coolant guides described may be joined together in a single operation within a brazing furnace, however other manufacturing alternatives may be used.

Coolant is delivered to each coolant guide through a coolant distribution system in the form of a network of tubing which is configured to deliver a similar rate of coolant flow to each coolant guide. The coolant distribution system is further configured to enable unwanted air within the system to be bled away from the coolant distribution system via an air bleed line. Described is the use of an optional automatic air vent which enables the air bleed line to be positioned below installed equipment, thus moving a potential point of failure to a safer location.

The described enclosure wall further comprises a lid which when fixed to the face component contains the coolant guides, structural supports, optional automatic air vent and coolant distribution system. The lid protects against leakage from any of the coolant guides, the coolant distribution system, the automatic air vent or other coolant carrying components by providing a secondary wall between installed equipment and any leaks.

Externally connectable fittings provide connections for coolant inlet and return lines, an air bleed line and optional fitting to access the internal space. These fittings can be positioned to be below any installed equipment when in operation.

When the lid is fixed to the face component, via a suitable joining process such as brazing or welding, the enclosure wall may be partially evacuated or pressurized via the optional internal access fitting. This allows for the installation of a pressure switch which if configured to change state when the pressure changes can be used to detect a leak or other breach within the enclosure wall and thus indicate to a monitoring system that the enclosure wall may have developed a problem before it would otherwise become apparent. A further benefit is that the enclosure wall, when fabricated with appropriate materials and joins, may be evacuated to a partial vacuum providing thermal insulation and reducing the heat loss or gain through parts of the enclosure wall where such heat loss or gain is unintended.

Also described is a method for manufacturing the described cooling enclosure wall, the method comprising: preparing the coolant guides for connection to a coolant distribution system; manufacturing a face component comprising a plurality of channels; positioning the coolant guides on the face component in such a way that coolant flowing through a coolant guide can cool a surface of one of the channels; fixing the cooling guides to the face component; manufacturing the coolant distribution system; connecting the coolant distribution system to the coolant guides; manufacturing a lid that will contain the coolant guides and coolant distribution system, and; fixing the lid to the face component.

A further aspect of the present disclosure is a method and apparatus for managing the temperature of coolant flowing through cooled enclosure apparatus to prevent condensation forming on the cooled enclosure or installed apparatus and to minimize the amount of heat lost from coolant to the surrounding air.

The described method comprises managing the temperature of the coolant flowing through cooled enclosure apparatus to be above the dew point but below the dry bulb temperature of air surrounding the cooled enclosure. This ensures that condensation will not form whilst simultaneously ensuring that the coolant does not heat the air, reducing the amount of work that air management equipment has to do.

Another aspect of the present disclosure is an exemplary data center coolant distribution configuration, the configuration comprising: facility coolant supply and return; a variable mixing valve; a pump; humidity, air temperature and coolant temperature instrumentation, and; a computerized controller. The computerized controller configured to read sensor information from the humidity, air temperature and coolant temperature sensors and to use that information to control the variable mixing valve to keep coolant temperature above the dew point and below the dry bulb temperature.

The configurations described can be applied to create zones within a larger data center environment with each zone independently controlled to supply coolant at the correct temperature for that particular zones environmental conditions. This concept can be applied to both container-based data centers, large data centers or smaller data centers with only one or two cooled enclosures.

The features of the present invention which are believed to be novel are set forth with particularity in the appended claims.

### BRIEF DESCRIPTION OF THE DRAWINGS

These and other features, aspects, and advantages of the present invention will become better understood with regard to the following description, appended claims, and accompanying drawings where:

FIG. 1 shows an exploded view of an exemplary enclosure wall in accordance with the principles of the present disclosure;

FIG. 2 shows an example of a standalone cooled enclosure comprising two of the enclosure walls of FIG. 1;

FIG. 3a shows an isometric view of the face component of the enclosure wall of FIG. 1;

FIG. 3b shows a partial side view of the face component of FIG. 3a;

FIG. 4a shows an isometric view of a coolant guide in accordance with the principles of the present disclosure;

FIG. 4b shows a front view of the coolant guide of FIG. 4a;

FIGS. 4c, 4d and 4e show alternative arrangements of the inlet and outlet portions of the coolant guide of FIG. 4a;

FIG. 4f shows the coolant guide of FIG. 4a augmented by a flat heatpipe;

FIG. 5a shows a partial isometric view of an alternative coolant guide in accordance with the principles of the present disclosure configured to provide redundant cooling;

FIG. 5b shows a front view of the coolant guide of FIG. 5a;

FIG. 6a shows a partial isometric view of an alternative coolant guide with an open profile in accordance with the principles of the present disclosure;

FIG. 6b shows a front view of the coolant guide of FIG. 6a;

FIG. 7 shows a partial isometric view of an alternative open coolant guide with a plurality of pins in accordance with the principles of the present disclosure;

FIG. 8a shows an exploded view of a partially assembled wall enclosure of FIG. 1 with the position of the coolant guide of FIG. 4a shown relative to a coolable surface of a channel of the face component of FIGS. 3a and 3b;

FIG. 8b shows a partial section through the assembly of FIG. 8a illustrating the positioning of coolant guides relative to the face component of FIGS. 3a and 3b;

FIG. 9a shows an exploded view of a partially assembled enclosure wall of FIG. 1 with the position of vertical frame supports, horizontal frame supports and vertical backbone supports shown relative to the face component of FIGS. 3a and 3b;

FIGS. 9b and 9c show partial sections of a partially assembled enclosure wall of FIG. 9a illustrating alternative vertical frame supports;

FIG. 10a shows an exploded view of a partially assembled enclosure wall of FIG. 1 illustrating the coolant distribution system;

FIG. 10b shows part of the coolant distribution system of FIG. 10a;

FIG. 11a is an exploded view of a partially assembled enclosure wall of FIG. 1 which shows the enclosure lid;

FIG. 11b shows a view of the lid of FIG. 11a in its installed position on the enclosure wall;

FIG. 12 illustrates a plurality of cooled enclosures and their connection to a coolant delivery system in accordance with the principles of the present disclosure, the coolant delivery system can be used to supply coolant to the cooled enclosures, and;

FIG. 13 illustrates an exemplary control system for controlling the coolant delivery system of FIG. 12.

### DETAILED DESCRIPTION

It is intended that the following description and claims should be interpreted in accordance with Webster's Third New International Dictionary, Unabridged unless otherwise indicated.

In the following specification and claims, a “heat transmitting means” or “heat transmitting device” is intended to encompass heatpipes, vapor chambers, thermosyphons, thermal interface materials and thermally conductive materials, composites, manufactures and apparatus such as: thermally conductive metals, examples of which include copper, aluminium, beryllium, silver, gold, nickel and alloys thereof; thermally conductive non-metallic materials, examples of which include diamond, carbon fiber, carbon nanotubes, graphene, graphite and combinations thereof; composite materials and manufactures, examples of which include graphite fiber/copper matrix composites and encapsulated graphite systems; thermally conductive filled plastics, examples of which include metal filled plastics, graphite filled plastics, carbon nanotube filled plastics, graphene filled plastics and carbon fiber filled plastics; and apparatuses such as liquid circulation, heat pumps and heat exchangers. A “heat transmitting means” or “heat transmitting device” is further intended to encompass any means presently existing or that is discovered in the future which transmits heat from one place to another.

Previous work by this inventor disclosed in patent cooperation treaty application published under no. WO 2014/030046 describes a rack enclosure into which rack mounted equipment can be installed, the content of which is incorporated herein by reference in its entirety. The rack mounted equipment being of a type which can be cooled by installation into a cooled rack enclosure and comprising a rail comprising a thermally conductive surface. The rack enclosure comprising a channel adapted to receive the rail of the rack mounted equipment when the equipment is installed into the enclosure and further comprising a coolable surface disposed on a surface of the channel in such a way that the coolable surface is adjacently located to the thermally conductive surface when the equipment is installed into the enclosure.

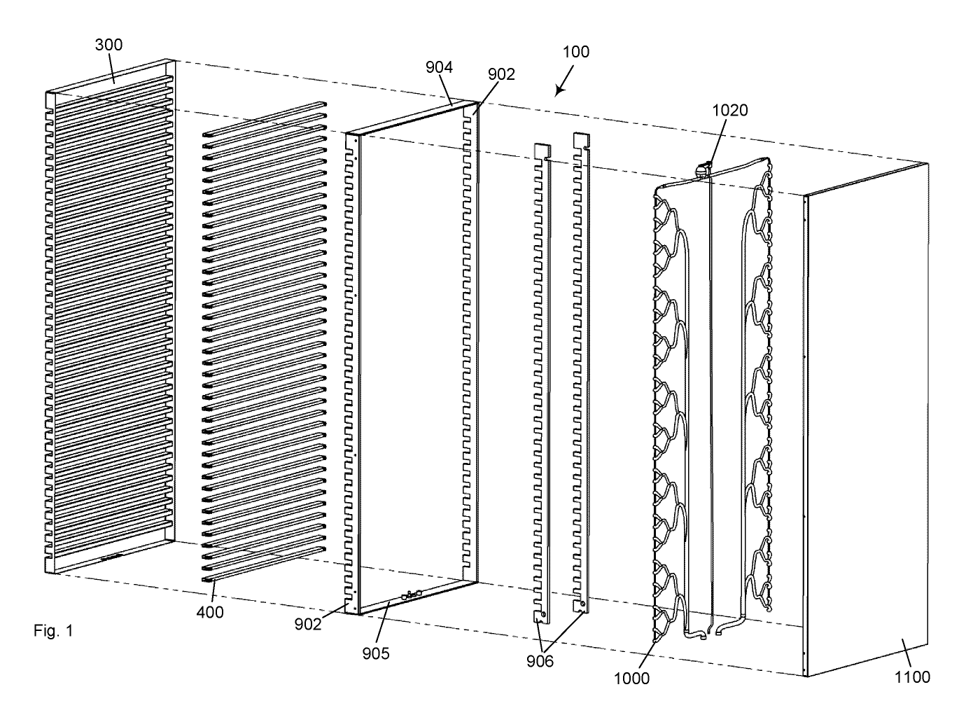

FIG. 1 shows an exploded view of a cooled enclosure wall 100, the enclosure wall comprising: face component 300; coolant guides 400; vertical frame supports 902; horizontal frame supports 904 and 905; vertical backbone supports 906; coolant distribution system 1000, including optional automatic air vent 1020, and; lid 1100. When these components are combined as described a robust, leak-resistant, failure-resistant, redundant-capable, thermally efficient cooled enclosure wall suitable for deployment in a mission critical data center environment can be created.

The enclosure wall shown in FIG. 1 can be integrated into either a standalone enclosure or as a component of a larger structure such as may be found in a container based data center. Illustrated in FIG. 2 is an example of a standalone cooled enclosure 200 which comprises two enclosure walls 100. The described enclosure wall 100 being configured to cool computer systems and other apparatus which are cooled by rails with a thermally conductive surface such as those described in WO 2014/030046 and the and the Patent Cooperation Treaty Patent Application entitled “Improved Rail Cooling Arrangement for Server Apparatus” filed concurrently by the same applicant and inventor.

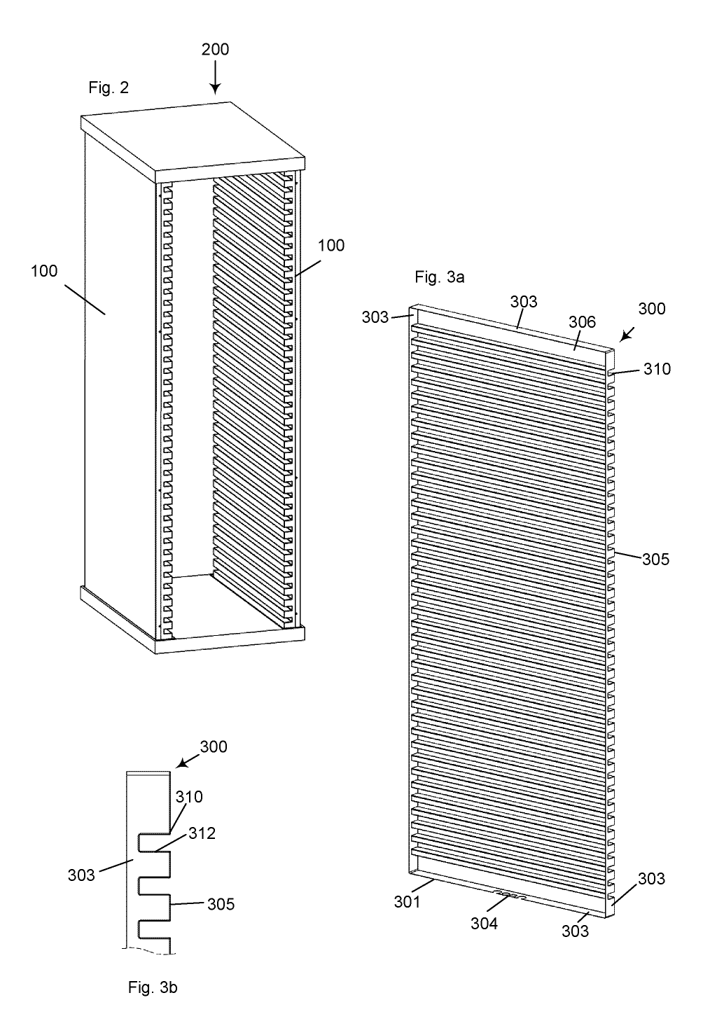

FIG. 3a shows an isometric view of the face component 300 of the enclosure wall 100 whilst FIG. 3b shows a partial side view of the face component 300. The face component 300 comprises a plurality of channels 310 which run across the width of the part, the channels each configured to receive a rail belonging to apparatus such as those described in WO 2014/030046 and the and the Patent Cooperation Treaty Patent Application entitled “Improved Rail Cooling Arrangement for Server Apparatus” filed concurrently by the same applicant and inventor. Each channel 310 comprises a surface which is designated as the “coolable surface”, this is the surface through which installed equipment will be cooled. The particular surface of the channel 310 which is to be used as the coolable surface is therefore defined by the intended use of the enclosure wall and one or more surfaces may be defined as a coolable surface, for the purposes of this disclosure we define the coolable surface to be the surface 312 which is the surface on each channel 310 which is closest to the bottom 301 of the enclosure wall 300.

The face component 300 illustrated comprises a rim or periphery 303 which runs around the perimeter of the part, the rim 303 will be discussed further below and comprises apertures 304 to permit access to the completed enclosure wall 100 from the outside, the use of the apertures 304 will also be discussed further below. For the purposes of this disclosure the front 305 of the face component 300 is defined as being the surface of the face component 300 which will face installed equipment and the rear 306 of the face component 300 is defined as being the opposing side. The face component 300 illustrated in FIG. 1 may be fabricated from a single piece of sheet metal such as steel or aluminum and may be manufactured by press forming. Understandably, any other means for fabricating the face component 300 may be used.

The wall enclosure 100 comprises a plurality of coolant guides which are disposed on the rear surface 306 of the face component 300, each coolant guide being positioned on and fixed to the face component 300 in such a way that coolant flowing through the coolant guide can cool the coolable surface 312 of at least one of the plurality of channels 310.

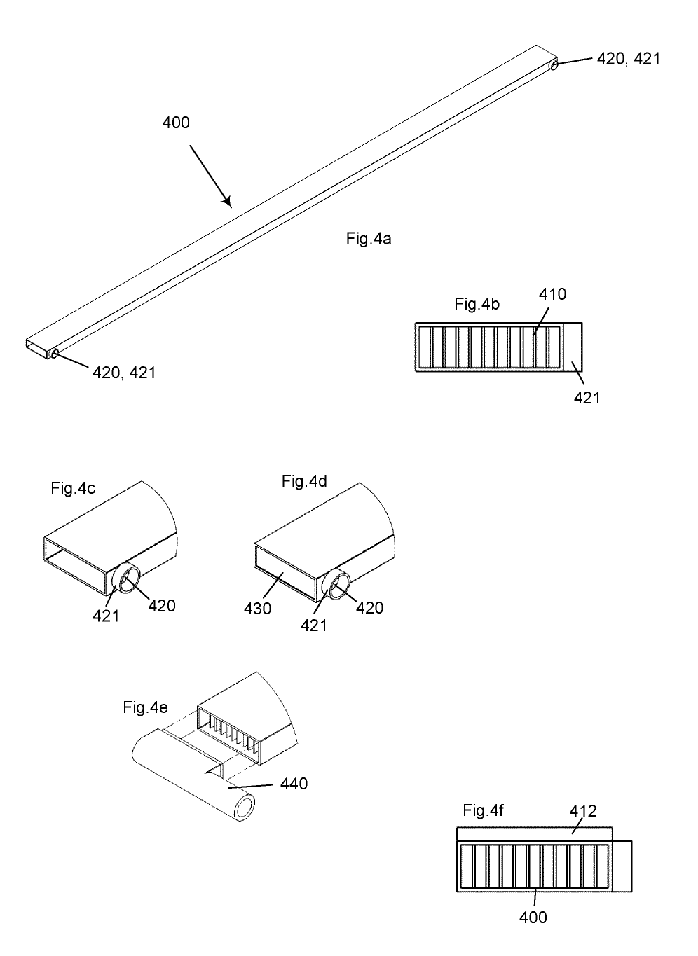

FIG. 4a shows an isometric view of one possible configuration of a coolant guide 400 and FIG. 4b shows a front view of coolant guide 400 which illustrates the internal structure. It can be seen that there are a plurality of thermally conductive features internal to the coolant guide 400 in the form of fins 410, these thermally conductive features increase the surface area over which coolant flows and thus may increase the heat removed by the coolant.

The coolant guide 400 shown is an extruded aluminium component, however one skilled in the art shall understand that the component may be made using any alternative process or any alternative material being thermally conductive such as, but not limited to, copper or steel or a thermally conductive plastic. Coolant guides fabricated as an aluminium extrusion have both good thermal conductivity and can be efficiently manufactured. Aluminium extrusions similar to those shown in FIG. 4a which comprise a plurality of internal fins, or chambers, are referred to as multi-port extrusions (MPE) or micro-channel tubing and are widely available from various manufacturers.

Each end of coolant guide 400 is prepared to be fitted to the coolant distribution system 1000. FIG. 4c shows one possible configuration comprising aperture 420 and optional lip 421, these form the inlet or outlet of coolant guide 400 and can be connected to the coolant distribution system 1000. In order to assist the escape of trapped air, apertures 420 are positioned such that air can escape from the coolant guide 400 through the apertures 420 when the enclosure wall 100 is in its operating position. When assembled the ends of the coolant guide 400 are sealed to prevent coolant escaping, thus forcing coolant introduced via one of the apertures 420 to flow through the coolant guide 400, across the thermally conductive features 410 and out the opposite aperture 420.

FIGS. 4c and 4d show alternative preparations of the end of coolant guide 400. Each extrusion has a portion of the internal structure, fins 410, removed to enable coolant introduced via aperture 420 to flow freely through each channel created by the fins 410. The coolant guide of FIG. 4c is shown as being open ended, in this configuration the ends of the coolant guide 400 are sealed when they are assembled into the wall enclosure 100 by either sealing them against the rim 303 of the face component 300 or against the surface of one of the vertical frame supports 902, vertical frame supports 902 are described further below. FIG. 4d shows an alternative preparation where the ends of the coolant guide 400 are sealed by fixing a plate 430 to seal the end of the coolant guide 400 before assembly. Alternatively the ends of the coolant guide 400 could be crimped closed or end-formed to produce the desired seal.

The optional lips 421 may comprise of an additional component, however if the apertures 420 are produced by a piercing process it may be possible to create both aperture 420 and the optional lips 421 without requiring an additional component. The lips 421 may be useful for securing a connection to the coolant distribution network. Alternatively the ends of the coolant guide 400 can be used as the inlet and outlet of the extrusion with no additional apertures being necessary, either end of the coolant guide 400 being connected to a coolant distribution system via a component configured to be fitted into either end, such an arrangement is illustrated in FIG. 4e which shows a component 440 adapted to fit into the end of a coolant guide 400.

In another embodiment, the coolant guide 400 may be augmented further by introducing a heat transmitting means, in this case in the form of a heatpipe which improves thermal communication between the coolable surface 312 of the face enclosure 300 and coolant being guided through the coolant guide 400. FIG. 4f illustrates a flat heatpipe 412 installed on a surface of the coolant guide 400, when installed the flat heatpipe 412 being sandwiched between the coolant guide 400 and the coolable surface 312. An alternative configuration which will achieve a similar result is to install the flat heatpipe 412 on the front 305 of the face component 300 such that the flat heatpipe is coincident with a coolable surface 312.

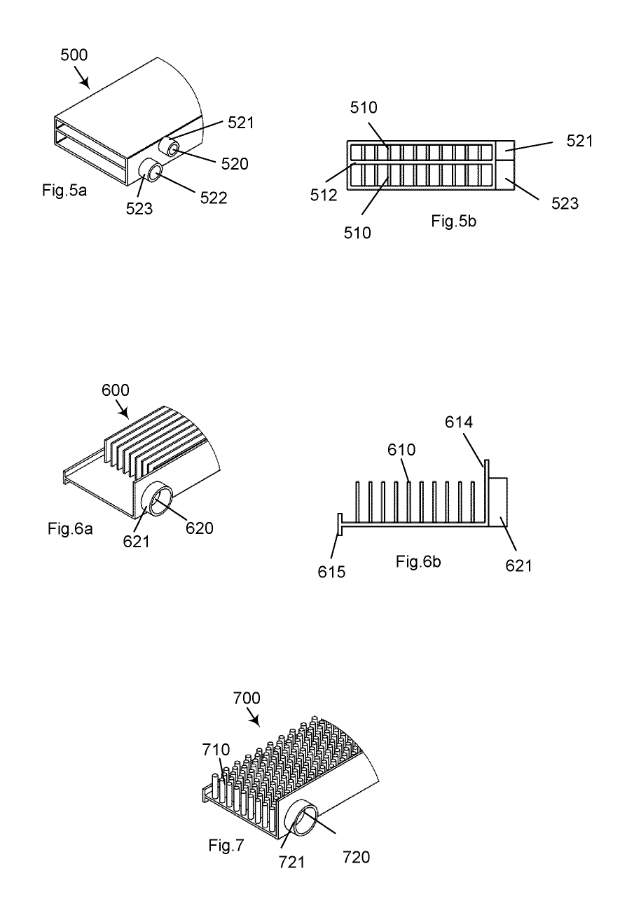

Now referring to FIG. 5a, a partial isometric view of another embodiment of a coolant guide 500 similar to the coolant guide 400 illustrated in FIGS. 4a-f is shown. Coolant guide 500 is an alternative embodiment to coolant guide 400 and is configured to support redundant cooling, coolant guide 500 similarly being an extruded aluminum component. FIG. 5b shows a front view of coolant guide 500 and illustrates the internal features including thermally conductive features 510 and separating feature 512. The coolant guide 500 comprises two separate guideways separated by the separating feature 512 which may be sealed and prepared in a manner similar to that described above for coolant guide 400. The coolant guide 500 providing two independent routes for coolant flow, thus enabling flow to be interrupted to one of the guideways without interrupting flow in the other. Coolant guide 500 further comprises apertures 520 and 522 and optional lips 521 and 523 to provide connection to a coolant distribution system.

Referring again to FIG. 5b it can be seen that the coolant guide 500 shown separates the upper and lower guideways via separating feature 512 such that the height of one guideway is greater than the other. Such a configuration typically allows that when installed with the smaller height guideway closer to the coolable surface 312 the larger height guideway, to which heat must travel farther to reach, can provide adequate cooling on its own. Understandably, such configuration is not essential.

FIG. 6a shows a partial isometric view of an alternative embodiment of a coolant guide 600 comprising an open configuration, FIG. 6b shows a front view and illustrates the thermally conductive features, in the form of fins 610, and features 614 and 615 which may reduce assembly difficulties introduced by the open configuration. With coolant guide 600 being an open extrusion the fins 610 can be brought into direct contact with the face component 300 and as such thermal efficiency may be improved whilst using less material when compared to closed coolant guide 400. However, it may be more complex to assemble and fix to the face component 300. Coolant guide 600 further comprises apertures 620 and optional lips 621 to provide a connection to a coolant distribution system.

FIG. 7 shows a partial isometric view of an alternative embodiment of a coolant guide 700 having an open configuration. Coolant guide 700 comprises a plurality of thermally conductive features in the form of pins 710. If made from a metal then coolant guide 700 could be manufactured by die casting or a forging process. If made from a thermally conductive plastic then coolant guide 700 could be manufactured by injection molding or another molding process. Coolant guide 700 further comprises apertures 720 and optional lips 721 to provide connection to a coolant distribution system.

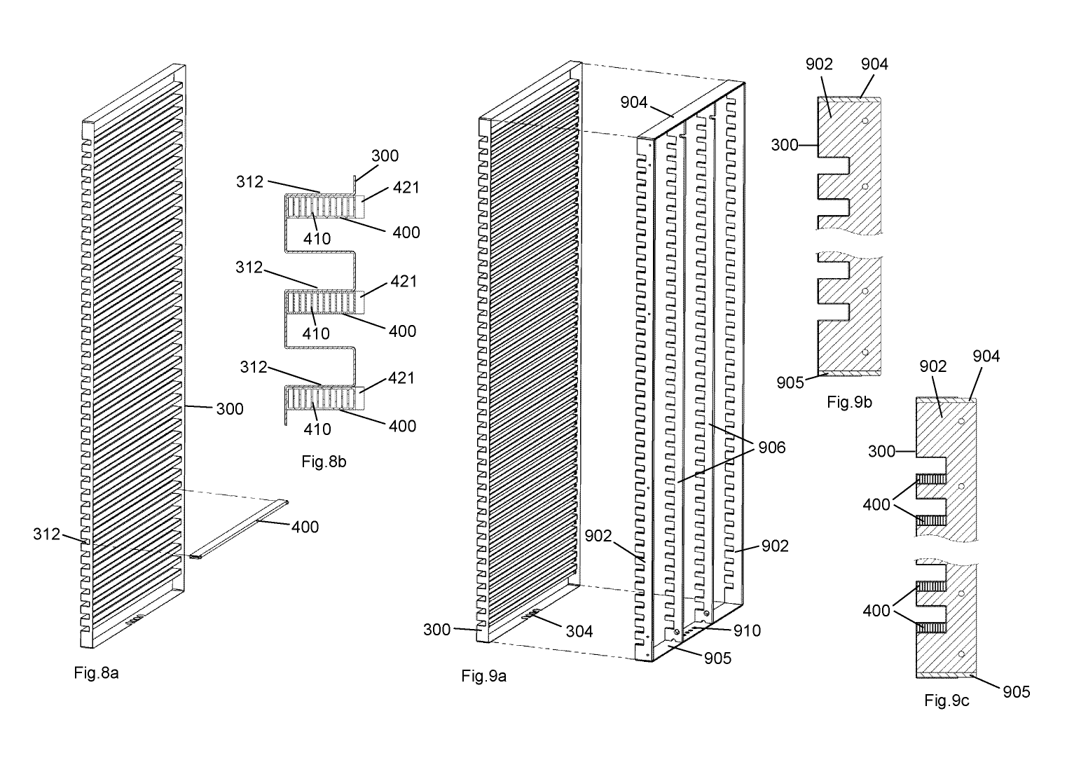

FIG. 8a shows an exploded view of a partially assembled enclosure wall 100, the view showing the positioning of a coolant guide 400 relative to a coolable surface 312 of a channel 310 of face component 300, FIG. 8b shows a partial section through face component 300 and illustrates the installed position of three coolant guides 400. The coolant guides 400 are positioned in such a way that a coolant flowing between inlet and outlet apertures 420 of a coolant guide 400 can cool the coolable surface 312 of a channel 310, alternative coolant guides 500, 600 and 700 are positioned in a similar manner.

Now referring to FIG. 8b, it can be seen by the position of optional lips 421 that the inlet and outlet apertures 420 remain accessible and that coolable surface 312 is in thermal communication with the coolant guides 400 and thermally conductive features 410. Referring back to FIG. 1, the enclosure wall 100 comprises a plurality of coolant guides 400 installed thereof wherein a coolant guide 400 is associated with each channel 310.

The method of fixing coolant guide 400 to face component 300 is dependent upon the materials used for each component, the fixing method however should: enable adequate thermal communication between the coolable surface 312 and thermally conductive features 410, and; provide a seal adequate to contain coolant within the coolant guide 400 if that is desired. In some cases this may be adequately achieved using a thermal adhesive or by soldering, brazing or welding if the materials permit. If both face component 300 and coolant guide 400 are made of aluminium the components may be brazed or soldered together. An adequate brazed or solder joint shall provide good thermal communication between components and may also be performed in a single process using a furnace, thus potentially reducing assembly costs.

Now referring to FIG. 9a, an exploded view of a partially assembled enclosure wall 100 is shown. The view shows the positioning of vertical frame supports 902, horizontal frame supports 904 and 905 and backbone supports 906. Supports 902, 904, 905 and 906 provide structural support to the enclosure wall 100. Frame supports 902, 904 and 905 are installed around the periphery of face component 300 whilst the vertical backbone supports 906 are installed between the vertical frame supports 902. FIGS. 9b and 9c illustrate another embodiment using alternative configurations for vertical frame supports 902. In such an embodiment, the vertical backbone supports 906 are similar in configuration. The vertical frame supports 902 are configured with a profile that supports the shape of face component 300 including the surfaces of the channels 310. The configuration illustrated in FIG. 9b configured to support the surfaces of channels 310, including directly supporting the coolable surface 312. The alternative configuration shown in FIG. 9c provides support for the surfaces of channel 310, including the coolable surface 312 through coolant guide 400. The vertical support surface 902 illustrated in FIG. 9b is also configured to provide a sealing surface for the ends of coolant guide 400.

The supports 902, 904, 905 and 906 also provide convenient points for attachment when the cooled enclosure 100 is fully assembled, such supports may comprise threaded holes or other points where fittings and other fasteners may be attached or fastened. Supports may also comprise additional features to provide access apertures for hoses or support for internal apparatus such as optional automatic air valve 1020. As illustrated in FIG. 9a the bottom horizontal frame support 905 provides features 910 where fittings can be attached, features 910 being aligned with apertures 304 of face component 300.

Supports may be manufactured from steel or aluminium or another material capable of bearing the required loads. However material selection for the supports is led by the structural requirements of the loads that the cooled enclosure wall 100 will be expected to endure during operation. In embodiments where the face component 300, coolant guides 400 and supports 902, 904, 905 and 906 are all made of aluminum, the joining of these components can be simplified by joining in a single operation within a brazing furnace.

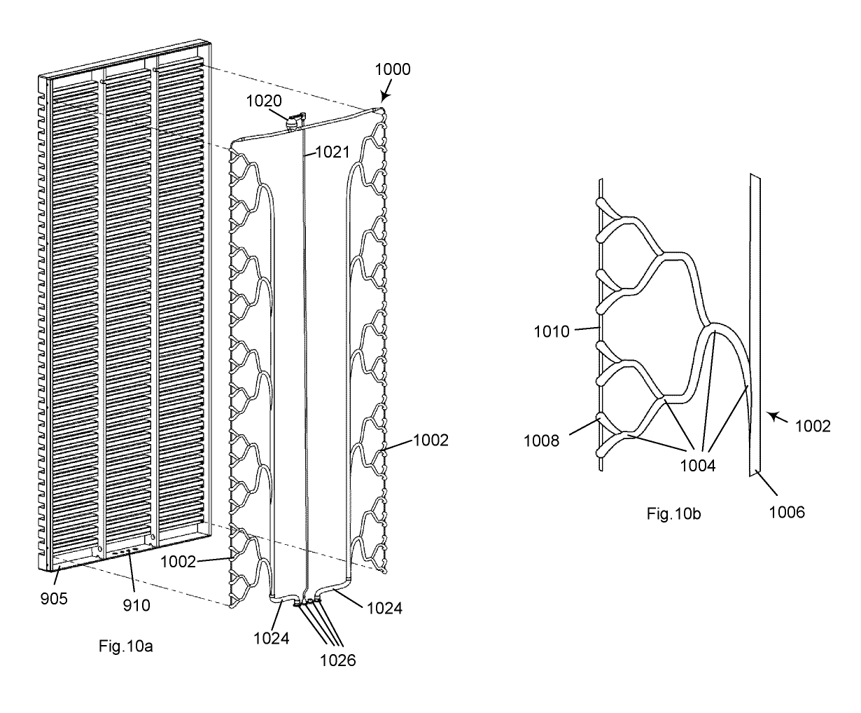

FIG. 10a is an exploded view of a partially assembled enclosure wall 100 illustrating the coolant distribution system 1000. The coolant distribution system 1000 typically comprising: tubing networks 1002; optional automatic air vent 1020; air vent line 1021; hoses 1024, and; fittings 1026. The fittings 1026 generally provides a connection between the coolant feed, return lines, the tubing networks 1002 and connecting air vent line 1021 to the external environment. The fittings 1026 are configured to provide access via apertures 910 in the horizontal frame support 905 and are optionally sealably fixed to the horizontal frame support 905. The fittings 1026 are optional and other arrangements for coolant feed and return are possible, including coolant feed and return lines being accessible via an aperture in the wall enclosure 100.

Hoses 1024 connect the coolant feed and return lines to tubing networks 1002 via the optional fittings 1026, the hoses may be flexible however it is not required. Depending on the joining methods that are used in the construction of the wall enclosure 100 it may be beneficial to fabricate hoses 1026 from a heat resistant material.

The optional automatic air vent 1020 provides a mechanism whereby air can be automatically vented from tubing networks 1002 through air vent line 1021. Whilst automatic air vent 1020 is shown as being an internal feature of wall enclosure 100, which will be further described below, it is not required and air may instead be vented via an automatic air vent or manual bleed valve which is externally located and connected to the coolant distribution system 1000 via a tube or any other hose arrangement. Alternatively there may be no air venting apparatus, with the system operating in an orientation where air can be vented via the coolant feed or return lines.

The tubing networks 1002 are connected to the inlet and outlet apertures of each coolant guide 400 and are configured to deliver an approximately similar rate of flow to each coolant guide 400. Now referring to FIG. 10b, part of tubing network 1002 is shown. The tubing network 1002 generally comprises a plurality of bifurcations 1004 which repeatedly split the coolant flow entering at an entry point 1006 until the coolant flow exits via an exit point 1008 at the inlet of a connected coolant guide 400. In order to deliver an approximately similar rate of flow to each coolant guide 400 each bifurcation 1004 is tuned or configured by modifying the size of each bifurcations exit apertures, by trial and error the tubing network 1002 can then be tuned to deliver an approximately similar rate of flow to each coolant guide 400. A computational fluid dynamics software or program may be used to find the optimal configuration of the components of the tubing network 1002.

One skilled in the art shall understand that the presence one or more bifurcations 1004 within the tubing network 1002 is optional as alternative tubing configurations or embodiments may be used to balance flow by restricting the coolant flow in an alternative manner. For example, in a further embodiment the tubing network may comprise a manifold with multiple channels or tubes exiting a single chamber, each channel or tube having a restriction which may be tuned or configured to deliver a balanced flow to each coolant guide.

In an alternative embodiment tubing network 1002 may be replaced by a simpler manifold arrangement connected to the coolant feed and coolant return lines, this approach may not deliver a similar rate of flow to each connected coolant guide, however adequate flow to each coolant guide may be achievable in this manner. An alternative embodiment comprising a tubing network 1002 connected to the coolant feed and a simpler manifold arrangement connected to the coolant return line may also be used to achieve a balanced flow when tuned or configured as described previously.

Referring back to FIG. 10b the tubing network 1002 may further comprise vent tube 1010 which connects each exit point 1008 to the optional automatic air vent 1020. Vent tube 1010 is located at what will be the high point of tubing network 1002 and connected coolant guides 400. Air can then be vented from the coolant distribution network 1000 and coolant guides 400 via vent tube 1010.

Embodiments of the tubing network 1002 may be manufactured from plastic and manufactured in two halves using a molding or casting process followed by a joining process. In other embodiments, the tubing network 1002 may be manufactured in two halves from a sheet metal, such as aluminium or steel, using a stamping process followed by a joining process such as brazing or welding. In a further embodiment, the tubing network 1002 may be manufactured as a single part, if that is desired, using any process of blow molding. In embodiments manufactured from aluminium, the tubing networks 1002 may also be joined to the coolant guides 400 and possibly other parts in a single joining process using a furnace.

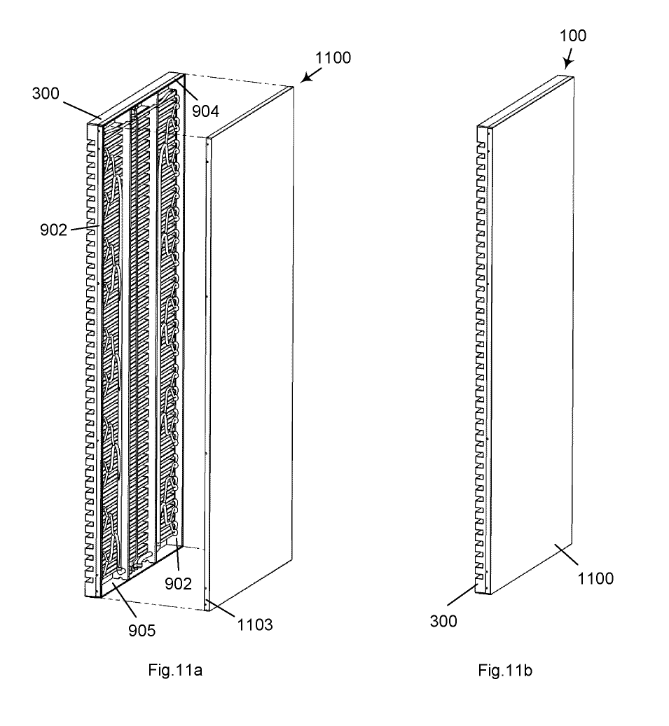

Now referring to FIG. 11a, an exploded view of a partially assembled enclosure wall 100 illustrating lid 1100 is shown. The lid 1100 is configured in such a way that the space enclosed by the lid 1100 and the face component 300 contains the coolant distribution system 1000 and the inlets and outlets of the coolant guides 400, in so doing creating a leak-resistant assembly.

The lid 1100 as shown in FIG. 11a is manufactured from sheet metal and comprises a rim 1103 similar to rim 303 of face component 300. When the lid 1100 is installed, if rims 1103 and 303 are joined then the entire enclosure wall 100 can be sealed to create a leak resistant container, thus any leakage within the coolant distribution system 1000, coolant guides 400 or any of the joints that comprise the various coolant distribution components can be controlled and directed in a safe manner, for example through a fitting installed in the horizontal frame support 905. In other embodiments, the lid 1100 could leave the bottom of the enclosure wall 100 open, allowing internal access whilst still providing some form of leak-resistance. Alternative materials such as plastic may also be used.

A potential benefit of face component 300 and lid component 1100 as described is that if rims 1103 and 303 are joined to create an air-tight seal and the various internal components such as the coolant guides 400 and coolant distribution system 1000 are also air-tight then the volume enclosed by the face component 300 and lid component 1100 can be pressurized or evacuated to create a higher or lower pressure environment, the pressure being modified through a fitting possibly being installed in bottom horizontal frame support 905. Leaks may then be detected by installing a pressure sensitive switch which is configured to change state when the pressure within the volume changes, such a switch could be installed in a similar manner as the fittings 1026 installed in the bottom horizontal frame support 905.

Another potential benefit of being able to evacuate the volume enclosed by face component 300 and lid component 1100 is that if a partial vacuum is introduced into that volume then, with the vacuum acting as heat insulation, heat lost or gained through parts of the enclosure that are not intended to be thermally active can be reduced.

In another embodiment, an alternative enclosure wall configuration may be used. The alternative enclosure wall comprising: face component 300; coolant guides 400, supports 902, 904, 905 and 906 and coolant distribution system 1000. The alternative enclosure wall being without a lid component. Whilst operable, the described alternative enclosure wall lacks some of the described benefits of the enclosure wall 100 such as improved leak-resistance.

The cooling technology described in Patent Cooperation Treaty application published as WO 2014/030046 and in the Patent Applications entitled “Computer System with Improved Thermal Rail” and “Robust Redundant-Capable Leak-Resistant Cooled Enclosure Wall”, can, with suitable compatible computer servers and other electronic equipment, be operated with a coolant temperature that is higher than the global maximum dew point of approximately 33° C. This therefore allows the use of a coolant which may be produced globally, all year round with evaporative cooling and in many locations with dry cooling for the majority of the year.

In order to maintain safe operation of a data center it is desirable to maintain the outer surfaces of cooled enclosures at a temperature above the dew point of the surrounding air, this will prevent formation of condensation and will therefore reduce the possibility of water damaging sensitive electronic equipment. Further, it may also be beneficial to maintain the temperature of the surfaces of the cooled enclosures below the dry bulb temperature of the surrounding air, this will prevent the surrounding air from being heated by the cooled enclosure and will reduce the work that air handling equipment needs to do.

This can be achieved by managing the temperature of the coolant flowing through cooled enclosure apparatus to be above the dew point of the surrounding air whilst also being below the dry bulb temperature of air surrounding the cooled enclosure.

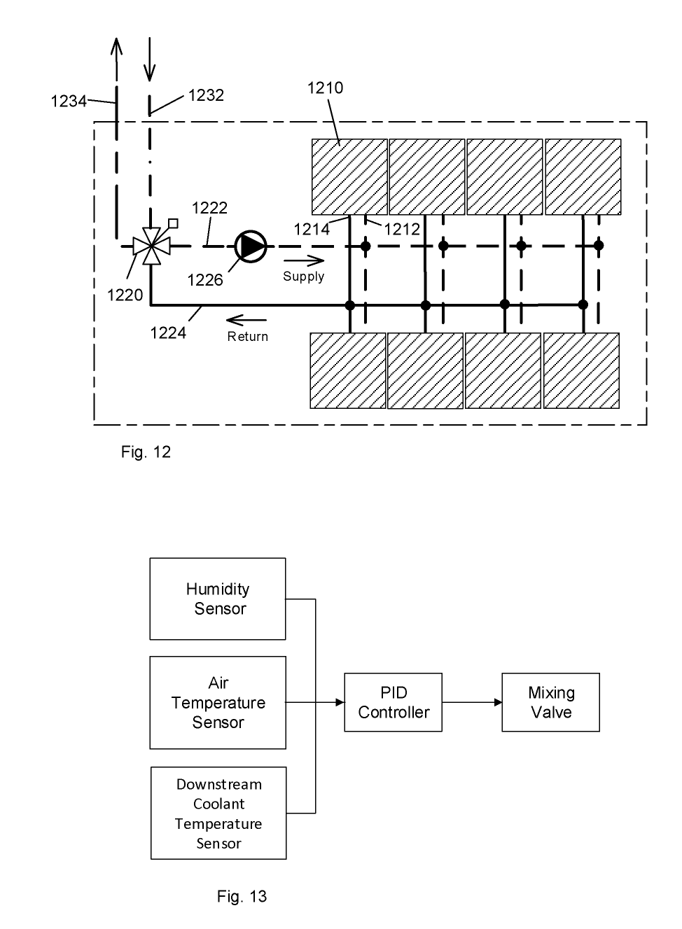

FIG. 12 illustrates a number of cooled enclosures 1210 comprising supply inlet 1212 and return outlet 1214 connected to a coolant delivery system which can be used to supply coolant to the cooled enclosures 1210. The coolant delivery system comprising a 4-way mixing valve 1220 which separates the pipework into an inner portion and an outer portion, the inner portion comprising supply piping 1222, represented by a dashed line, and return piping 1224, represented by a solid line. The outer portion comprising coolant supply piping 1232, represented by a dash dot line, and coolant return piping 1234, represented by a long dash dash line.

The inner portion further comprising a pump 1226 and connections 1212 and 1214 to the various cooled enclosures 1210, the pump 1226 driving coolant through each enclosure via the supply inlets 1212 and return outlets 1214. The outer portion, comprising coolant supply 1232 and coolant return 1234, represents the facility cooling supply, the facility cooling supply being cooled by cooling apparatus, not shown, such as a cooling tower, chiller unit, heat exchanger or other apparatus.

When the 4-way mixing valve 1220 is fully closed, coolant circulates around the inner portion with no mixing with coolant from the outer portion. When the 4-way mixing valve 1220 is fully open, coolant flows from the outer portion through the inner portion and out into the outer portion with no recirculation. The 4-way mixing valve can also be operated to allow coolant flowing in from the outside portion to mix with coolant circulating within the inner portion. Thus by controlling the 4-way mixer valve 1220, the temperature of coolant being supplied to the cooled enclosures 1210 can be managed by mixing only the necessary amount of coolant from the facility coolant supply 1232.

Systems which use a similar configuration of mixer valve and inner and outer portions are well known by those having ordinary skill in the art of hydronics, a particular example being radiant heating systems for greenhouses. Alternative configurations using 3-way mixer valves and other alternative apparatus to those described are also known to those having ordinary skill in the art of hydronics.

FIG. 13 illustrates the inputs and outputs for a computerized controller which can control the mixer valve 1220 to obtain the desired coolant temperature range. The computerized controller receiving inputs from: one or more air temperature sensors which are located in proximity to the cooled enclosures 1210, the air temperature sensors measuring the temperature of the air surrounding the cooled enclosures 1210; one or more downstream coolant temperature sensors measuring coolant temperature flowing through the supply piping 1222 downstream of the mixing valve 1220, the downstream coolant temperature sensors measuring the temperature of coolant before it is used to cool equipment within the cooled enclosures 1210 and preferably before it enters the cooled enclosures 1210, and; one or more humidity or dew point sensors which are located in proximity to the cooled enclosures 1210, the humidity or the dew point sensors measuring the humidity or the dew point of the air surrounding the cooled enclosures 1210.

The computerized controller receives the input from the various sensors and determines the dew point, coolant temperature and dry bulb temperatures. A control algorithm, for example a PID algorithm or a trainable machine learning algorithm, uses the input data to operate the mixing valve 1220 in such a way that the coolant temperature entering the cooled enclosures 1210 is above the measured dew point whilst remaining below the measured dry bulb temperature.

Alternatively if additional information is provided to the computerized controller including: flow rates, mixer valve dimensions and specifications, and temperatures of coolant flowing through the return piping 1224 and coolant supply piping 1232, then a control algorithm can be developed to provide optimal mixing and thus control the coolant temperature entering cooled enclosures 1210.

The described method and apparatus can be used by a data center either to manage coolant temperature for the entire facility through a single mixer valve or to split the facility into multiple zones, each of which is managed independently.

Although specific embodiments of the invention have been shown and described herein, it is to be understood that these embodiments are merely illustrative of the many possible specific arrangements that can be devised in application of the principles of the invention. Numerous and varied other arrangements can be devised by those of ordinary skill in the art without departing from the scope and spirit of the invention.

1. A cooled enclosure of the type which cools installed equipment by thermal contact between a surface of a portion of installed equipment and a surface of the cooled enclosure, the cooled enclosure comprising a multi-port extrusion coolant guide in thermal contact with the surface of the cooled enclosure.

2. A wall of a cooled enclosure, the cooled enclosure of the type which cools installed equipment by thermal contact, the wall comprising:
a channel comprising a coolable surface;
a first coolant guide comprising inlet and outlet apertures, and;
a plurality of thermally conductive features in thermal contact with the coolable surface, the thermally conductive features being disposed within the first coolant guide in such a way that a coolant flowing between the inlet and the outlet apertures flows across at least some portion of the thermally conductive features.

3. The wall of claim 2, wherein the thermally conductive features are fins.

4. The wall of claim 2, wherein the thermally conductive features are pins.

5. The wall of claim 2, wherein the thermally conductive features are projections projecting from a surface in thermal contact with the coolable surface.

6. The wall of claim 2, wherein the first coolant guide is manufactured by an extrusion process.

7. The wall of claim 2, wherein the first coolant guide is a multi-port extrusion and the thermally conductive features comprise a wall of the multi-port extrusion.

8. (canceled)

9. The wall of claim 2, wherein the first coolant guide comprises a first guideway and a second guideway, the first coolant guide configured such that coolant flowing in the first guideway is separated from coolant flowing in the second guideway.

10. The wall of claim 2, further comprising:
a second coolant guide, and;
a tubing network connected to the inlet aperture of the first coolant guide and the inlet aperture of the second coolant guide.

11. The wall of claim 10, wherein the tubing network is configured to deliver an approximately similar rate of coolant flow to the first coolant guide and the second coolant guide.

12. The wall of claim 11, wherein the tubing network is bifurcated.

13. The wall of claim 2, the wall further comprising a coolant distribution system comprising
a tubing network connected to the inlet aperture of the first coolant guide, and;
an automatic air-vent connected to the tubing network.

14. A wall of a cooled enclosure, the wall comprising:
a plurality of channels comprising a coolable surface, each channel configured to receive a rail portion of installed equipment;
a coolant distribution system;
one or more coolant guides, each having an inlet and an outlet which are both connected to the coolant distribution system, the coolant guides being configured to guide the flow of a coolant entering the guide from the inlet to allow the cooling of at least a portion of the coolable surface of at least one of the channels before exiting via the outlet, and;
a lid component being adapted to be joined to the plurality of channels in such a way that the space enclosed by the lid component and the plurality of channels contains at least a part of the coolant distribution system and the inlet and outlet of the one or more coolant guides.

15. The wall of claim 14, the space enclosed by the lid component and the plurality of channels being sufficiently sealed to allow a modified pressure environment.

16. The wall of claim 14, the modified pressure environment being created by evacuating air.

17. The wall of claim 15, the wall further comprising a pressure sensitive switch configured to change state when the state of the modified pressure environment is changed.

18. The wall of claim 14, wherein at least two of the one or more coolant guides are configured to independently cool a portion of the same coolable surface.

19.-36. (canceled)

37. A cooled enclosure which cools installed equipment by thermal contact between a surface of a portion of installed equipment and a surface of the cooled enclosure, the cooled enclosure being configured such that the surface of the cooled enclosure is maintained at a temperature below a dry bulb temperature of surrounding air.

38. The cooled enclosure of claim 37, the cooled enclosure being further configured such that the surface of the cooled enclosure is further maintained at a temperature above a dew point of the surrounding air.

39. A cooled enclosure which cools installed equipment by thermal contact between a surface of a portion of installed equipment and a surface of the cooled enclosure, the cooled enclosure being configured such that the surface of the cooled enclosure is maintained at a temperature above a dew point of surrounding air.

40. The cooled enclosure of claim 39, the cooled enclosure being further configured such that the surface of the cooled enclosure is further maintained at a temperature below a dry bulb temperature of the surrounding air.
